(19) United States
(12) Patent Application Publication
(10) Pub. No.: US 2025/0344445 A1
(43) Pub. Date: Nov. 6, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Kuei-Yu KAO, Hsinchu (TW); Chiung-Yu CHO, Hsinchu (TW)

(21) Appl. No.: 18/654,076

(22) Filed: May 3, 2024

(51) Int. Cl. H01L 29/423; H01L 21/3065; H01L 21/8234; H01L 27/088; H01L 29/06; H01L 29/08; H01L 29/66; H01L 29/775; H01L 29/786

(52) U.S. Cl. CPC H10D 30/6735; H01L 21/3065; H10D 30/014; H10D 30/43; H10D 30/6757; H10D 62/121; H10D 62/151; H10D 84/013; H10D 84/0135; H10D 84/038; H10D 84/83

(57) ABSTRACT

Embodiments of the present disclosure provide methods for forming semiconductor device structures. The method includes forming a fin structure from a substrate, depositing a first sacrificial layer around the fin structure, depositing a second sacrificial layer on the first sacrificial layer, and depositing a first mask layer over the second sacrificial layer. The first mask layer has a thickness ranging from about 60 nm to about 65 nm. The method further includes performing a first etch process to remove portions of the first mask layer, performing multiple processes to remove portions of the second sacrificial layer to form two or more sacrificial gate electrode layers, removing a portion of the fin structure to expose a substrate portion, and forming a source/drain region over the substrate portion.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure, in accordance with some embodiments.

FIG. 6 is a cross-sectional side view of the semiconductor device structure taken along line A-A of FIG. 5, in accordance with some embodiments.

FIGS. 7A-7G are cross-sectional side views of various stages of manufacturing the semiconductor device structure taken along line A-A of FIG. 5, in accordance with some embodiments.

FIG. 8 illustrates pulsing schemes of a plasma power and a bias power of an etch process, in accordance with some embodiments.

FIG. 9 illustrates pulsing schemes of a plasma power and two bias powers of an etch process, in accordance with some embodiments.

FIGS. 10A-10C are various views of one of various stages of manufacturing the semiconductor device structure, in accordance with some embodiments.

FIGS. 11 and 12 are cross-sectional side views of various stages of manufacturing the semiconductor device structure, in accordance with some embodiments.

FIGS. 13A and 13B are cross-sectional top views of the semiconductor device structure taken along line B-B and line C-C of FIG. 12, respectively, in accordance with some embodiments.

FIG. 14 is a cross-sectional side view of one of various stages of manufacturing the semiconductor device structure, in accordance with some embodiments.

FIGS. 15A and 15B are cross-sectional top views of the semiconductor device structure taken along line D-D and line E-E of FIG. 14, respectively, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a method to form a semiconductor device structure. The method includes patterning a sacrificial layer to form one or more sacrificial gate electrode layers. The patterning process uses a mask structure including an oxide layer having a thickness ranging from about 60 nm to about 65 nm. The oxide layer having such thickness may help minimize residue formed on the one or more sacrificial gate electrode layers. As a result, gate electrode layer defects and electrical short between the gate electrode layer and the source/drain region are reduced.

While the embodiments of this disclosure are discussed with respect to nanostructure channel FETs, such as Horizontal Gate All Around (HGAA) FETs, Vertical Gate All Around (VGAA) FETs, Forksheet FETs, implementations of some aspects of the present disclosure may be used in other processes and/or in other devices, such as FinFETs, planar FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

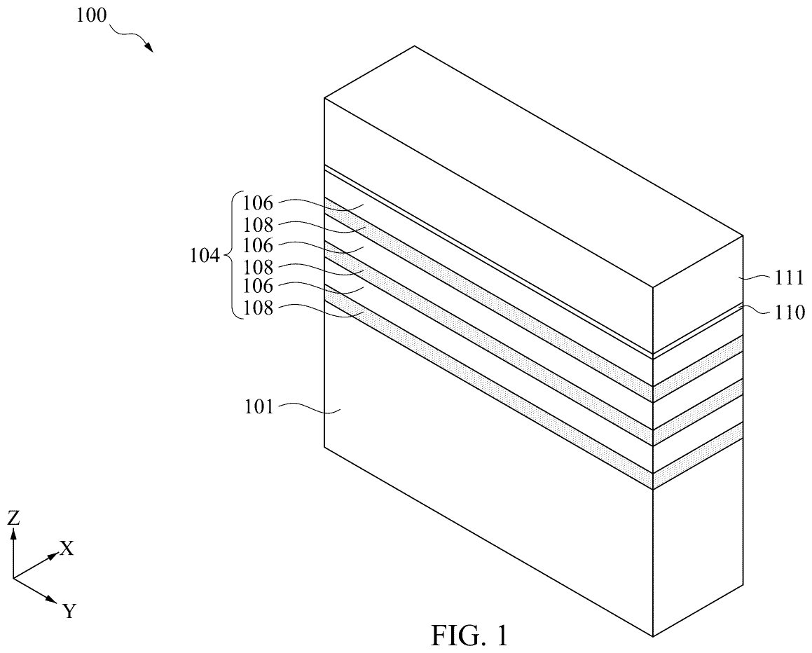

FIGS. 1-15B show exemplary processes for manufacturing a semiconductor device structure 100 according to embodiments of the present disclosure. It is understood that additional operations can be provided before, during, and after processes shown by FIGS. 1-15B, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

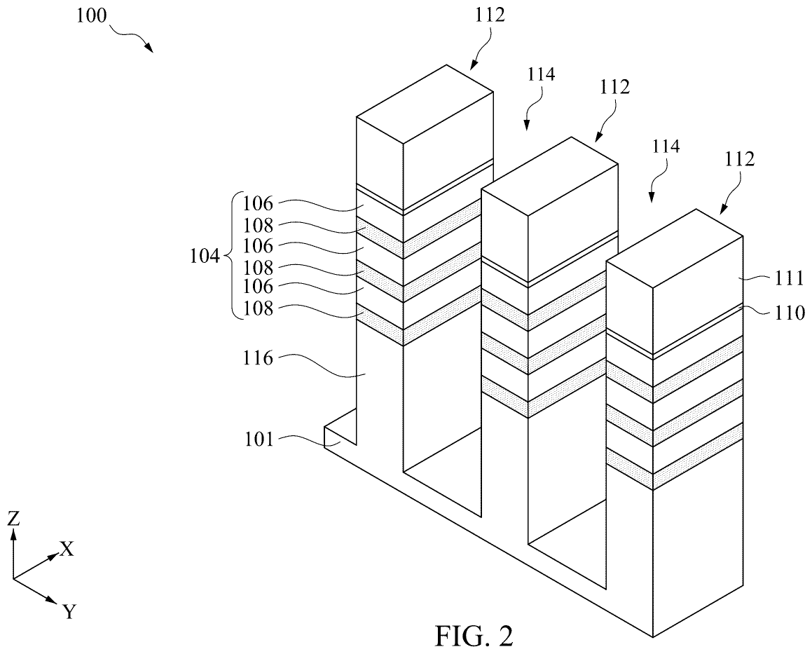

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

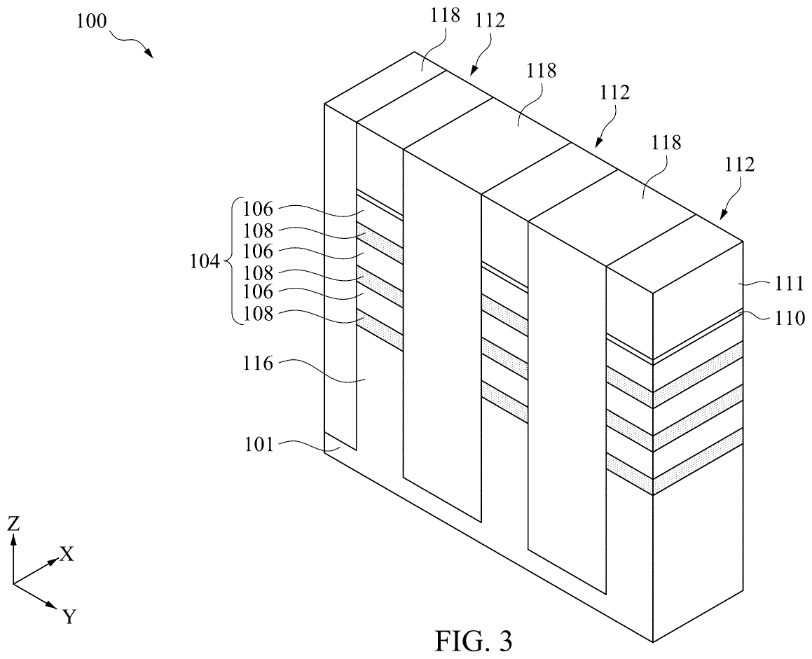

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

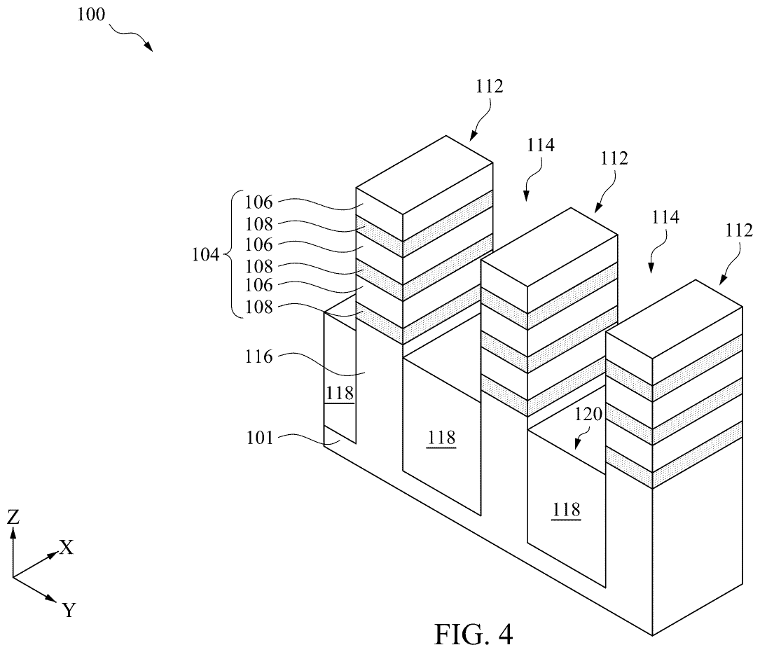

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the STI. In some embodiments, the oxide layer 110 and the nitride layer 111 are also removed during the recessing of the insulating material 118.

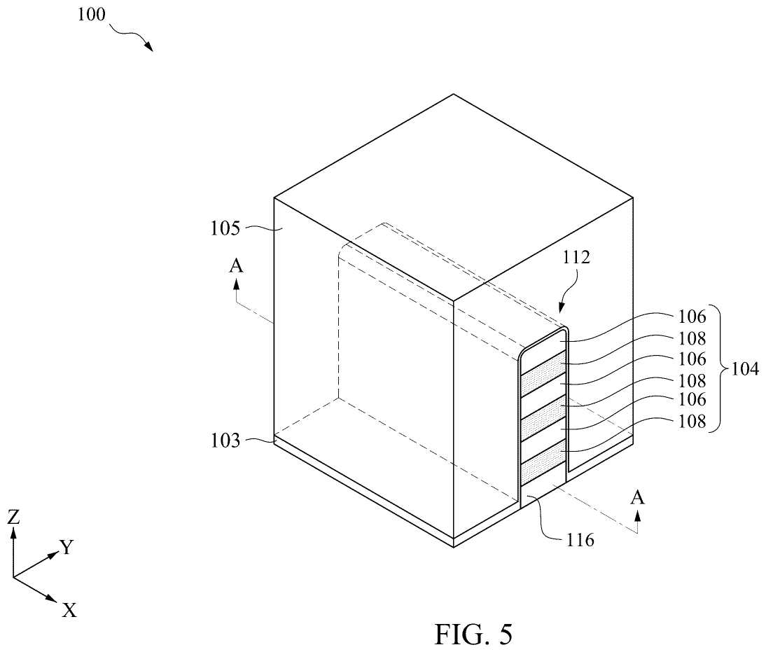

In FIG. 5, a first sacrificial layer 103 is formed on the exposed surfaces of the semiconductor device structure 100, and a second sacrificial layer 105 is formed on the first sacrificial layer 103. In some embodiments, the first sacrificial layer 103 includes a dielectric material, such as an oxide, for example silicon oxide. The first sacrificial layer 103 may be formed by any suitable process, such as CVD or PECVD. In some embodiments, the first sacrificial layer 103 is a conformal layer formed by a conformal process, such as atomic layer deposition (ALD). The first sacrificial layer 103 may have a thickness in the Z direction ranging from about 3 nm to about 5 nm. In some embodiments, the second sacrificial layer 105 includes a semiconductor material, such as polysilicon. The second sacrificial layer 105 may be formed by any suitable process, such as CVD, PECVD, ALD, or PVD. The second sacrificial layer 105 may be first deposited to embed the fin structures 112, followed by a planarization process, such as a CMP process. In some embodiments, the second sacrificial layer 105 may have a thickness in the Z direction ranging from about 50 nm to about 60 nm.

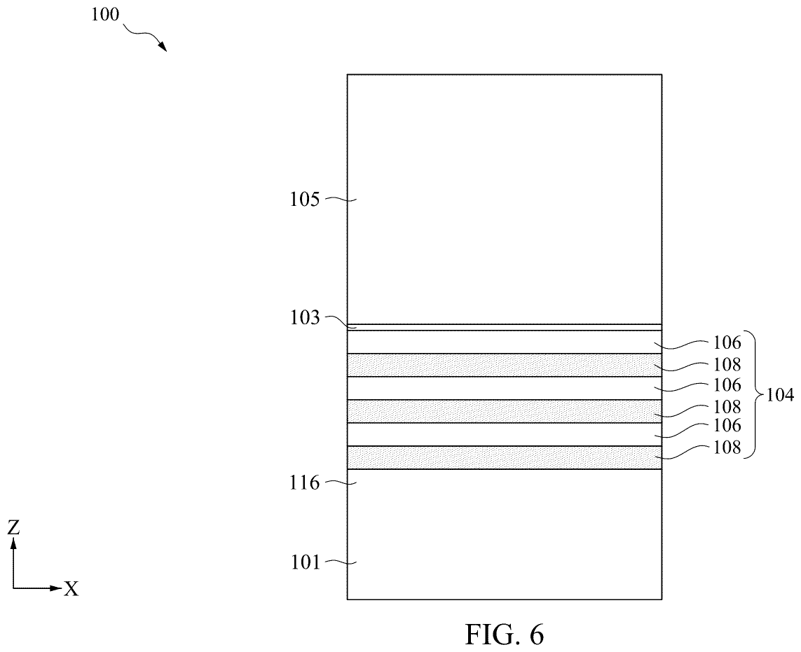

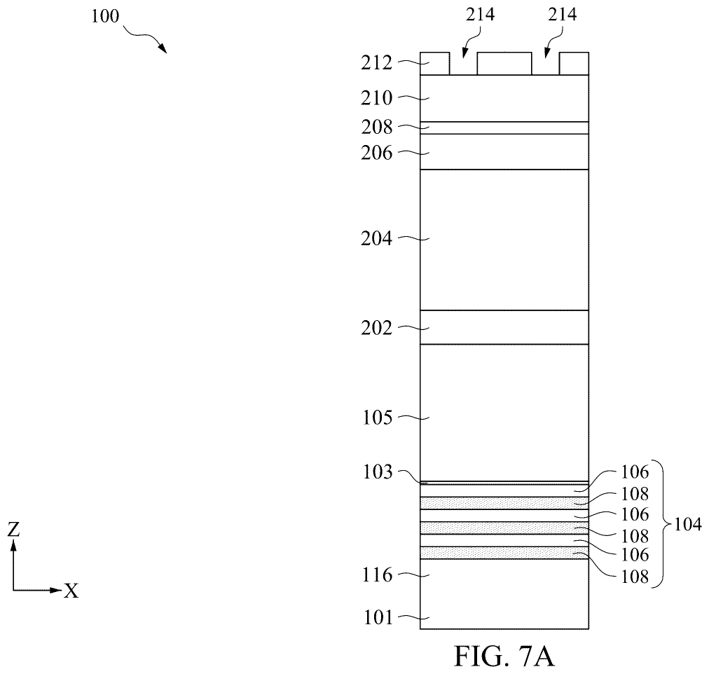

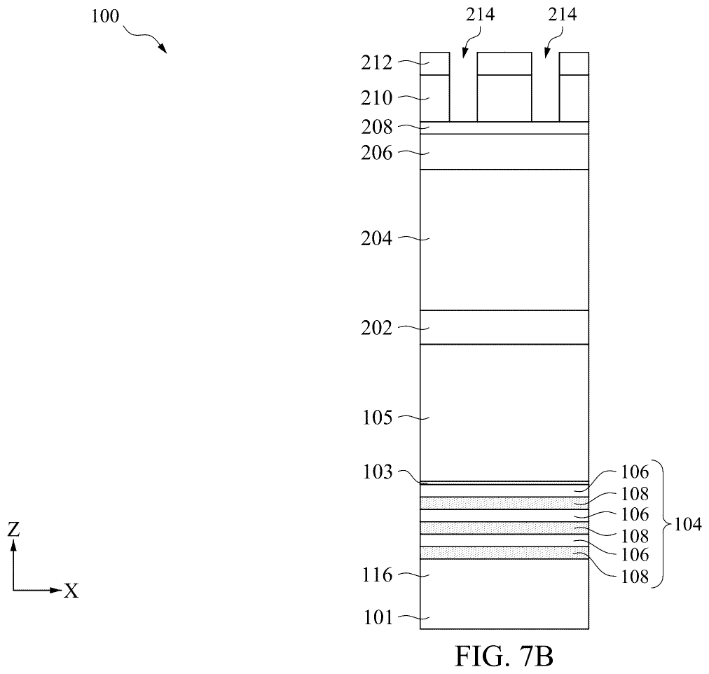

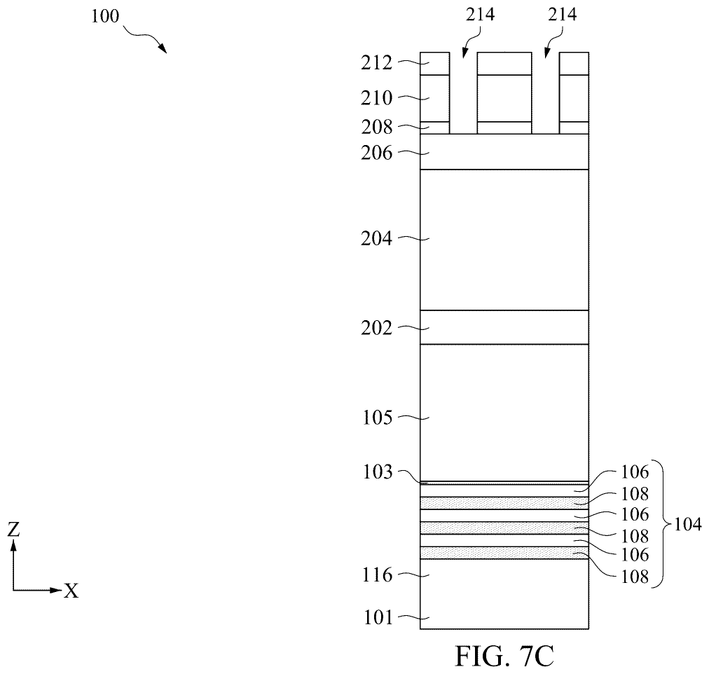

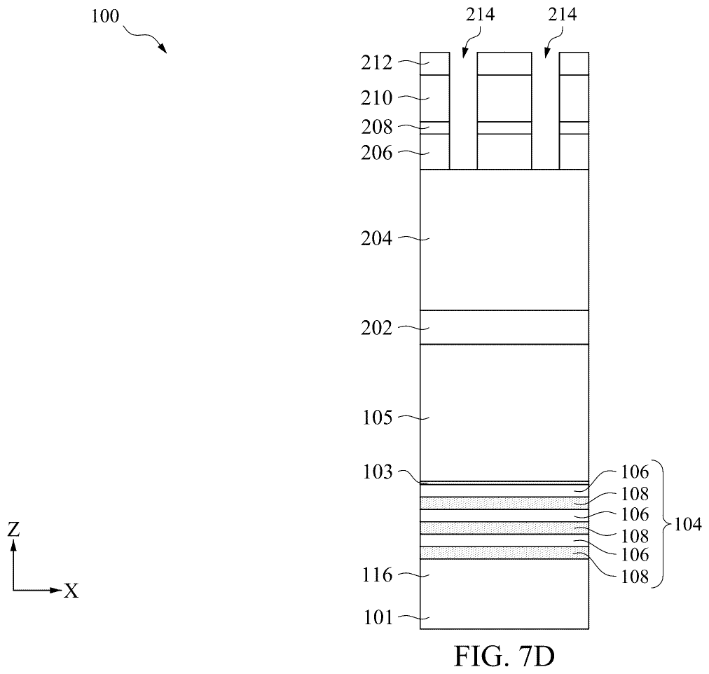

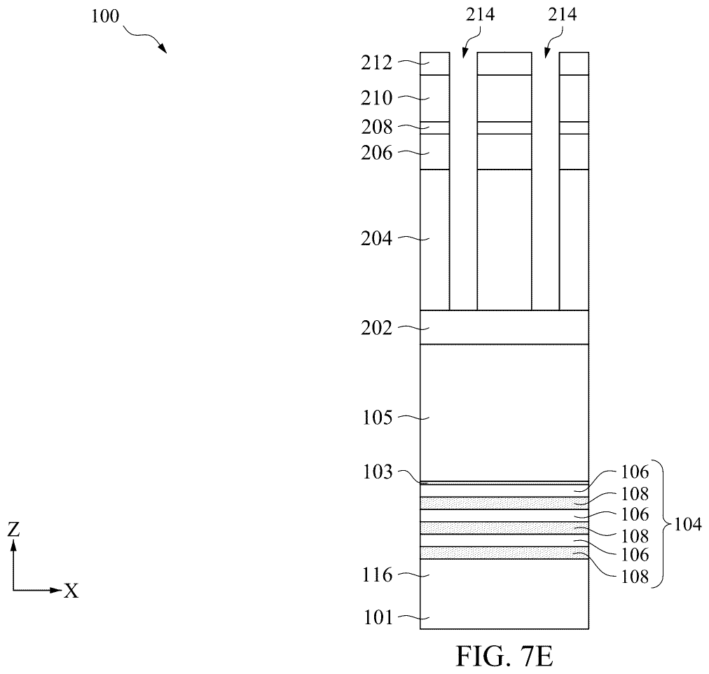

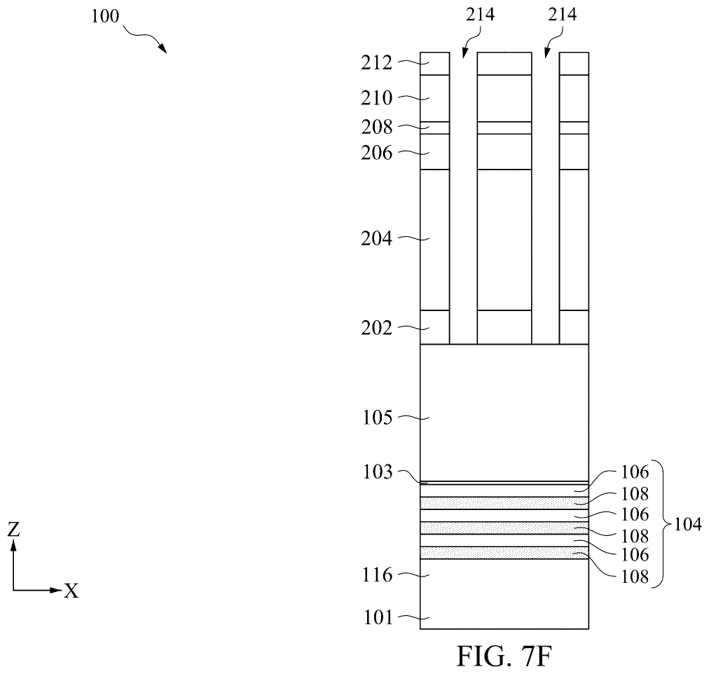

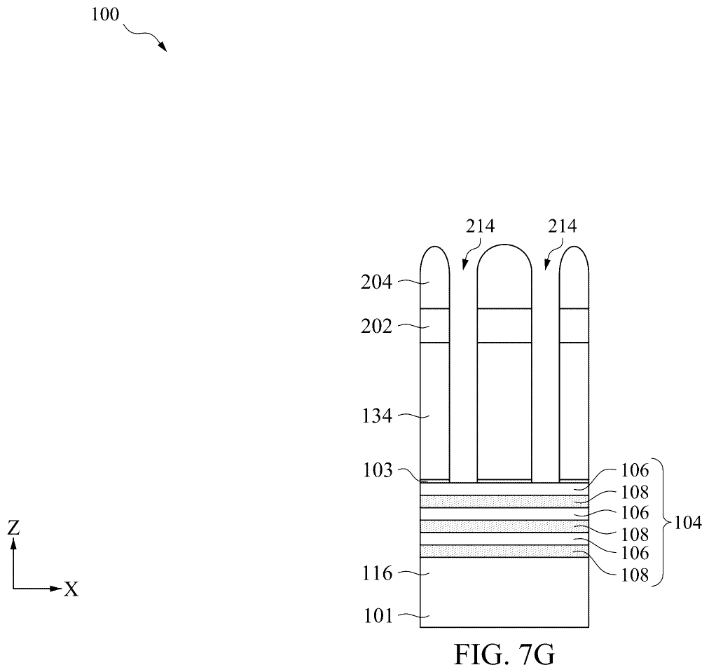

FIG. 6 is a cross-sectional side view of the semiconductor device structure 100 taken along line A-A of FIG. 5, in accordance with some embodiments. FIGS. 7A-7G are cross-sectional side views of various stages of manufacturing the semiconductor device structure 100 taken along line A-A of FIG. 5, in accordance with some embodiments. FIGS. 7A-7G illustrate a method to form one or more sacrificial gate electrode layers 134 (FIG. 7G) having minimum amount of residue. As shown in FIG. 7A, a plurality of mask layers are formed on the second sacrificial layer 105. In some embodiments, the plurality of mask layers includes a first mask layer 202 disposed on the second sacrificial layer 105, a second mask layer 204 disposed on the first mask layer 202, a third mask layer 206 disposed on the second mask layer 204, a fourth mask layer 208 disposed on the third mask layer 206, a fifth mask layer 210 disposed on the fourth mask layer 208, and a sixth mask layer 212 disposed on the fifth mask layer 210. In some embodiments, the fourth mask layer 208, the fifth mask layer 210, and the sixth mask layer 212 form a resist structure. For example, the resist structure may be a tri-layer photoresist. The fourth mask layer 208 may be a bottom layer, the fifth mask layer 210 may be a middle layer, and the sixth mask layer 212 may be a photoresist layer. The fourth mask layer 208 and the fifth mask layer 210 are made of different materials such that the optical properties and/or etching properties of the fourth mask layer 208 and the fifth mask layer 210 are different from each other. In some embodiments, the fourth mask layer 208 may be a carbon layer, and the fifth mask layer 210 may be a silicon-rich layer designed to provide an etch selectivity between the fifth mask layer 210 and the fourth mask layer 208. The sixth mask layer 212 may be a chemically amplified photoresist layer and can be a positive tone photoresist or a negative tone photoresist. The sixth mask layer 212 may include a polymer, such as phenol formaldehyde resin, a poly(norbornene)-co-malaic anhydride (COMA) polymer, a poly(4-hydroxystyrene) (PHS) polymer, a phenol-formaldehyde (bakelite) polymer, a polyethylene (PE) polymer, a polypropylene (PP) polymer, a polycarbonate polymer, a polyester polymer, or an acrylate-based polymer, such as a poly (methyl methacrylate) (PMMA) polymer or poly (methacrylic acid) (PMAA). The sixth mask layer 212 may be formed by spin-on coating. The sixth mask layer 212 may be patterned to have openings 214 formed therein.

In some embodiments, the first mask layer 202 may be a SiN layer and has a thickness ranging from about 20 nm to about 30 nm, the second mask layer 204 may be an oxide layer, such as a silicon oxide layer, and has a thickness ranging from about 60 nm to about 65 nm, the third mask layer 206 may include the same material as the first mask layer 202 and has a thickness ranging from about 20 nm to about 30, the fourth mask layer 208 has a thickness ranging from about 40 nm to about 50 nm, and the fifth mask layer 210 has a thickness ranging from about 20 nm to about 30 nm.

As shown in FIG. 7B, the openings 214 are extended through the fifth mask layer 210. In some embodiments, a first etch process is performed to remove portions of the fifth mask layer 210. The first etch process may be any suitable process. In some embodiments, a plasma etch process is performed to extend the openings 214 through the fifth mask layer 210. The plasma etch process may use a carbon-based etchant, such as CHF₃, CH₃F, CF₄, and/or C₄F₆. Carrier gas or passivation gas, such as N₂ and/or He, may flow along with the etchant. The plasma power of the plasma etch process may range from about 500 W to about 2000 W, and the process pressure may range from about 10 mT to about 50 mT.

As shown in FIG. 7C, the openings 214 are extended through the fourth mask layer 208. In some embodiments, a second etch process is performed to remove portions of the fourth mask layer 208. The second etch process may be any suitable process. In some embodiments, a plasma etch process is performed to extend the openings 214 through the fourth mask layer 208. The plasma etch process may use an oxygen-based etchant, such as SO₂ and/or O₂, and He may flow along with the etchant to assist with the plasma etch process. The plasma power of the second etch process may be greater than the plasma power of the first etch process. In some embodiments, the plasma power of the second etch process ranges from about 1000 W to about 4000 W. The process pressure of the second etch process may be less than the process pressure of the first etch process. In some embodiments, the process pressure of the second etch process ranges from about 1 mT to about 20 mT.

As shown in FIG. 7D, the openings 214 are extended through the third mask layer 206. In some embodiments, a third etch process is performed to remove portions of the third mask layer 206. The third etch process may be any suitable process. In some embodiments, a plasma etch process is performed to extend the openings 214 through the third mask layer 206. The plasma etch process may use the same etchant and other gases as the first etch process, with the exception of N₂ gas. In some embodiments, additional etchants, such as HBr and/or O₂, may be used in the third etch process. The plasma power of the third etch process may be less than the plasma power of the second etch process. In some embodiments, the plasma power of the third etch process ranges from about 500 W to about 2000 W. The process pressure of the third etch process may be substantially the same as the process pressure of the second etch process.

As shown in FIG. 7E, the openings 214 are extended through the second mask layer 204. In some embodiments, a fourth etch process is performed to remove portions of the second mask layer 204. The fourth etch process may be any suitable process. In some embodiments, a plasma etch process is performed to extend the openings 214 through the second mask layer 204. The plasma etch process may use a carbon-based etchant, such as CHF₃, CH₃F, CF₄, and/or C₄F₆. Carrier gas or passivation gas, such as Ar and/or O₂, may flow along with the etchant. The plasma power of the fourth etch process may be less than the plasma power of the first etch process. In some embodiments, the plasma power of the fourth etch process ranges from about 10 W to about 100 W. The process pressure of the fourth etch process may be substantially the same as the process pressure of the third etch process.

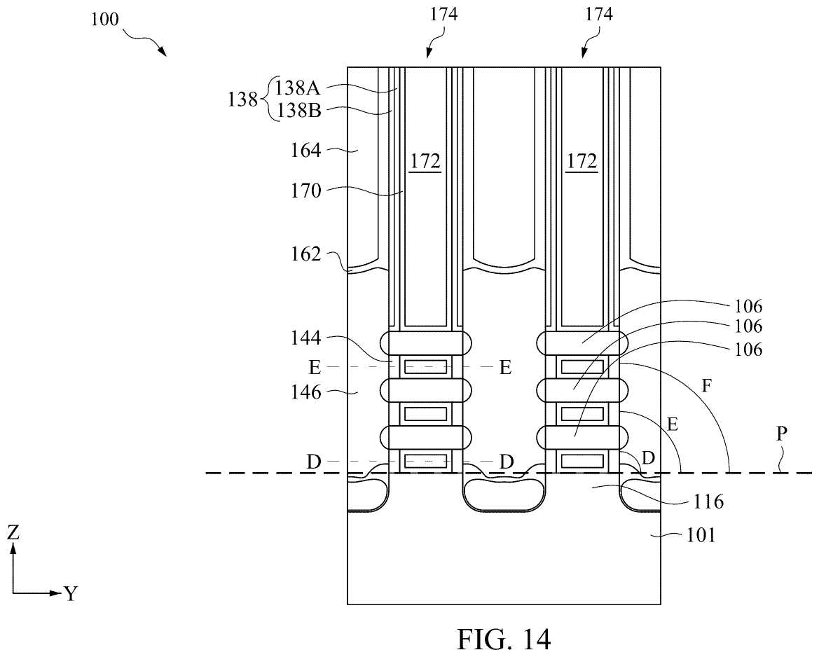

As described above, in some embodiments, the thickness of the second mask layer 204 ranges from about 60 nm to about 65 nm. The fourth etch process is performed to extend the openings 214 through the second mask layer 204 having the thickness ranging from about 60 nm to about 65 nm. In some embodiments, the thickness of the second mask layer 204 ranges from about 90 nm to about 150 nm. In such embodiment, a fifth etch process is performed to remove portions of the thicker second mask layer 204. The fifth etch process is different from the fourth etch process. The fifth etch process may include the same etchant and other gases as the fourth etch process. However, the process pressure of the fifth etch process is higher than that of the fourth etch process. Furthermore, the process time of the fifth etch process is substantially longer than the fourth etch process. With the thicker second mask layer 204, the aspect ratio of the openings 214 is higher after the formation of the sacrificial gate electrode layers 134 (FIG. 7G) compared to the aspect ratio of the openings 214 with the thinner second mask layer 204. The high aspect ratio of the openings 214 can lead to residue formed in corners of the subsequently formed sacrificial gate electrode layers 134 (FIG. 7G), which can lead to defective gate electrode layers 172 (FIG. 14). By reducing the thickness of the second mask layer 204, the aspect ratio of the openings 214 is lowered. The lowered aspect ratio of the openings 214 may help minimize residue formed in the corners of the sacrificial gate electrode layers 134. Thus, the fourth etch process is different from the fifth etch process due to the different thicknesses of the second mask layer 204. The lower process pressure of the fourth etch process can enhance vertical ions in the plasma. Furthermore, in some embodiments, the flow rates of the etchants and/or other gases of the fourth etch process may be substantially slower than those of the fifth etch process.

As shown in FIG. 7F, the openings 214 are extended through the first mask layer 202 to expose portions of the second sacrificial layer 105. In some embodiments, a sixth etch process is performed to remove portions of the first mask layer 202. The sixth etch process may be any suitable process. In some embodiments, the sixth etch process is similar to the third etch process, with the exception of using Ar instead of HBr and He.

As shown in FIG. 7G, the openings 214 are extended through the second sacrificial layer 105 to form the sacrificial gate electrode layers 134. In some embodiments, multiple processes are performed to remove portions of the second sacrificial layer 105. The multiple processes may include a main etching process, a breakthrough process, a soft landing process, and an over etching process. The main etching process may be a plasma etch process and may utilize etchants and other gases such as Cl₂, HBr, CH₂F₂, CHF₃, CH₃F, O₂, and/or Ar. The process pressure of the main etching process may range from about 40 mT to about 800 mT, and the plasma power of the main etching process may range from about 200 W to about 1500 W. The breakthrough process may be performed after the main etching process. In some embodiments, the breakthrough process is a plasma etch process and may utilize etchants and other gases such as CF₄, C₄F₆, CHClF₂, and/or Ar. The process pressure of the breakthrough process may range from about 1 mT to about 100 mT, and the plasma power of the breakthrough process may range from about 50 W to about 1000 W. In some embodiments, an ash process may be performed between the main etching process and the breakthrough process. The ash process may be a plasma process and may utilize gases such as CO₂, CH₄, SO₂, and/or Ar. The process pressure of the ash process may range from about 1 mT to about 100 mT, and the plasma power of the ash process may range from about 500 W to about 4000 W.

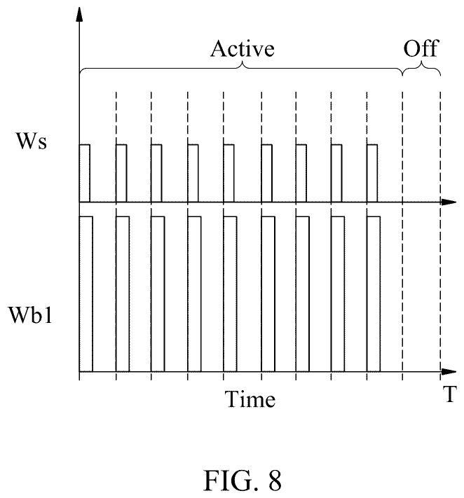

After the breakthrough process, the soft landing process may be performed. The soft landing process may be a plasma etch process and may utilize etchants and gases such as Cl₂, HBr, CH₂F₂, CF₄, C₄F₆, CHClF₂, HF, O₂, and/or Ar. In some embodiments, the soft landing process has a plasma power ranging from about 100 W to about 500 W. The plasma power may be generated by a first radio frequency (RF) power source, and the plasma power may be pulsed. In some embodiments, the soft landing process has a bias power ranging from about 600 W to about 1200 W. The bias power may be generated by a second RF power source that is different from the first RF power source. The plasma power and the bias power may be pulsed. FIG. 8 illustrates pulsing schemes of the plasma power and the bias power.

As shown in FIG. 8, in some embodiments, the plasma power Ws and the bias power Wb1 has the same pulsing scheme. The pulsing scheme shown in FIG. 8 is for a time period T. In some embodiments, the time period T ranges from about 5 ms to about 15 ms, such as about 10 ms. Within the time period T, the pulsing scheme has an active period and an off period. In some embodiments, the active period is about 80 percent to about 90 percent of the time period T, while the off period is about 10 percent to about 20 percent of the time period T. The off period may follow the active period. As shown in FIG. 8, during the active period, the plasma power Ws has a duty cycle of about 1 percent to about 6 percent, such as about 3 percent. In other words, the plasma power is pulsed multiple times during the active period. During the off period, the plasma power Ws is turned off. As shown in FIG. 8, during the active period, the bias power Wb1 has duty cycle of about 1 percent to about 8 percent, such as about 4 percent. In other words, the bias power is pulsed multiple times during the active period. During the off period, the bias power Wb1 is turned off. The pulsing scheme in time period T may be repeated multiple times during the soft landing process. In some embodiments, the soft landing process has a time duration ranging from about 10 s to about 60 s.

In some embodiments, due to the smaller thickness of the second mask layer 204, the openings 214 have a smaller aspect ratio, which can lead to re-deposition of byproducts. During the plasma etch processes, byproducts, such as SiO, SiO—Cl, SiO—HBr, SiO—N, or SiO—Ar, may be formed and may re-deposit on the surfaces of the semiconductor device structure 100. These byproducts may negatively affect the etching of the second sacrificial layer 105. The pulsing schemes of the plasma power Ws and the bias power Wb1 help reduce the re-deposition of byproducts. For example, during the off period, the plasma power Ws and the bias power Wb1 are turned off, and the vacuum pump is still running to remove byproducts from the processing chamber. As a result, re-deposition of byproducts is reduced.

In some embodiments, an optional passivation process may be performed after the soft landing process, and an optional second soft landing process may be performed after the passivation process. The passivation process protects the vertical surfaces of the second sacrificial layer 105. In some embodiments, the passivation process is a plasma treatment process using a nitrogen-containing plasma. The plasma power of the passivation process may range from about 500 W to about 4000 W and has a duty cycle ranging from about 3 percent to about 20 percent. The process pressure of the passivation process may range from about 50 mT to about 300 mT. The optional second soft landing process may be the same as the soft landing process described above.

Next, a flush process is performed. The flush process may be a plasma etch process that removes the byproducts from the surfaces of the semiconductor device structure 100. The flush process may utilize etchants such as CF₄ and/or C₄F₆ and may have a plasma power ranging from about 50 W to about 1000 W. The process pressure of the flush process may range from about 1 mT to about 100 mT. By removing the byproducts from the semiconductor device structure 100, less residue may be formed in the corners of the subsequently formed sacrificial gate electrode layer 134.

After the flush process, the over etching process is performed. The over etching process may be a plasma etch process and may utilize etchants and gases such as Cl₂, HBr, CH₂F₂, CF₄, C₄F₆, CHClF₂, HF, O₂, and/or Ar. The process pressure of the over etching process may range from about 40 mT to about 800 mT. The plasma power of the over etching process may range from about 300 W to about 1000 W. In some embodiments, in order to further remove the byproducts, a second bias power source may be used to provide a second bias power during the over etching process. For example, the over etching process may include a first bias power ranging from about 400 W to about 1200 W and a second bias power ranging from about 10 W to about 200 W. The duty cycles of the plasma power, the first bias power, and the second bias power may range from about 3 percent to about 20 percent.

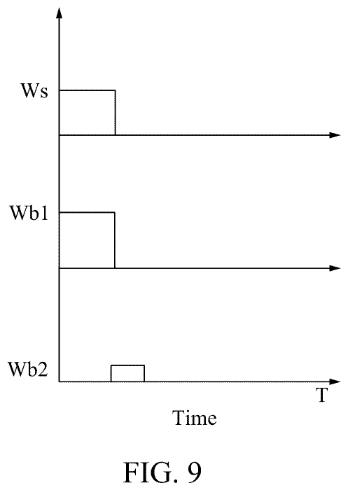

FIG. 9 illustrates pulsing schemes of a plasma power and two bias powers of the over etching process, in accordance with some embodiments. As shown in FIG. 9, in some embodiments, the plasma power Ws of the over etching process and the first bias power Wb1 of the over etching process has the same pulsing scheme, while the second bias power Wb2 of the over etching process has a different pulsing scheme compared to those of the plasma power Ws and the first bias power Wb1. In some embodiments, the duty cycles of the plasma power Ws and the first bias power Wb1 are 20 percent, while the duty cycle of the second bias power is 10 percent. In some embodiments, the second bias power Wb2 is turned on after the first bias power Wb1 is turned off, as shown in FIG. 9.

After the over etching process, the second sacrificial layer 105 is patterned to form two or more sacrificial gate electrode layers 134, as shown in FIG. 7G. The third, fourth, fifth and sixth mask layers 206, 208, 210, 212 may be removed during or before the patterning of the second sacrificial layer 105. The first and second mask layers 202, 204 may remain on the sacrificial gate electrode layers 134, as shown in FIG. 7G. As a result of the thinner second mask layer 204 and the processes to pattern the second sacrificial layer 105, the residue formed in the corner of the sacrificial gate electrode layer 134 may be reduced or eliminated. For example, the pulsing schemes of the plasma power and the bias power of the soft landing process include an off period, which helps to remove the byproducts. The flush process also removes the byproducts. Furthermore, the additional bias power applied during the over etching process further removes the byproducts. The low aspect ratio of the openings 214 along with the reduced amount of byproducts lead to the sacrificial gate electrode layers 134 with small amount or free of residue in the corners.

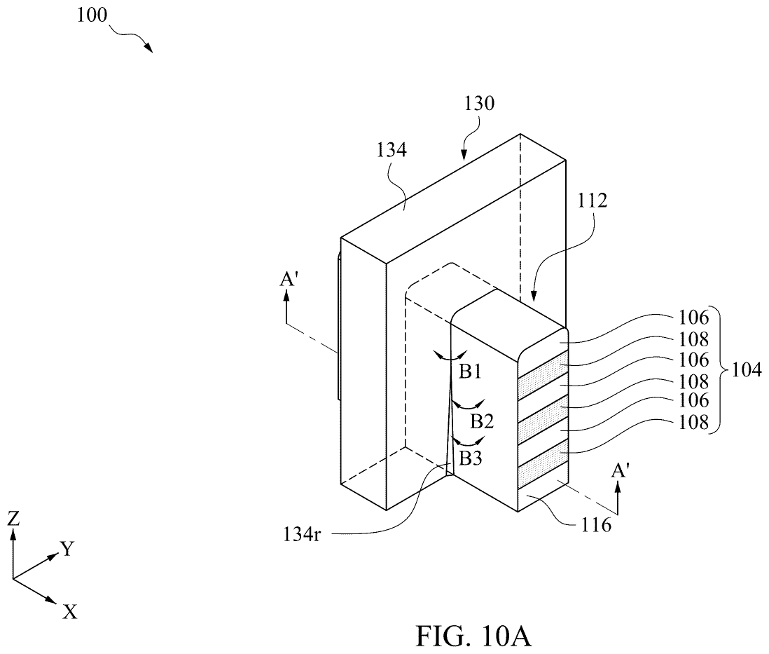

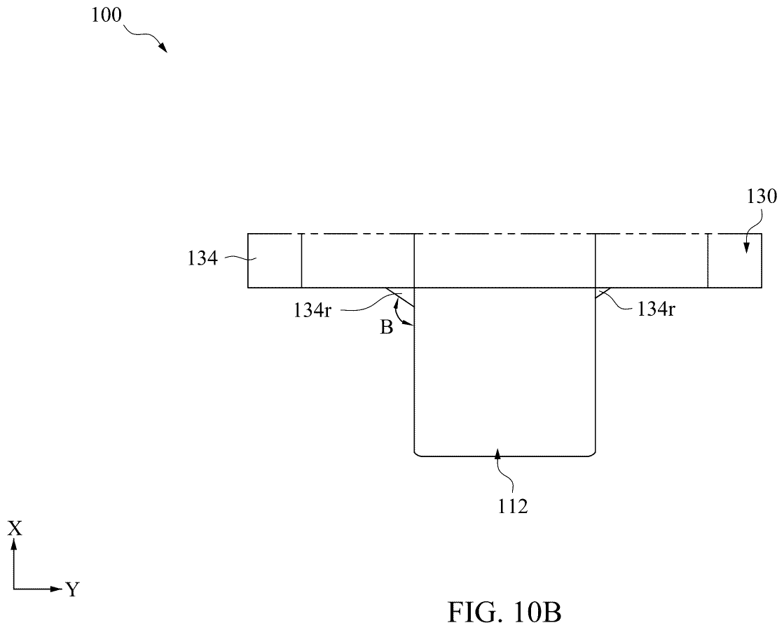

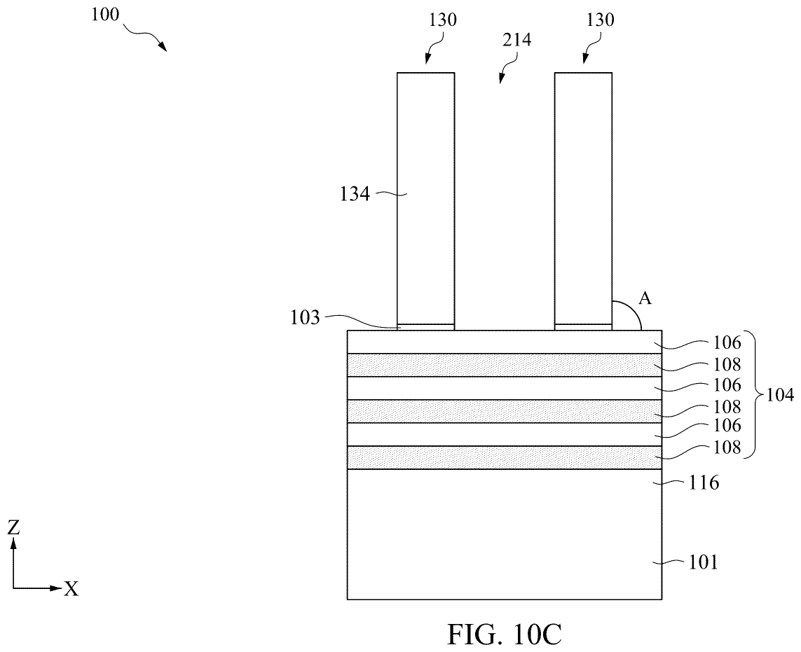

FIGS. 10A-10C are various views of one of various stages of manufacturing the semiconductor device structure 100, in accordance with some embodiments. The first and second mask layers 202, 204 are omitted in FIGS. 10A-10C for clarity. FIG. 10B is a top view of the semiconductor device structure 100 shown in FIG. 10A, and FIG. 10C is a cross-sectional side view of the semiconductor device structure 100 taken along line A′-A′ of FIG. 10A. As shown in FIGS. 10A-10C, the first sacrificial layer 103 may be also patterned by an etch process. A small amount of residue 134r, which may be a portion of the second sacrificial layer 105, may be formed in the corners between the sacrificial gate electrode layer 134 and the stack of semiconductor layers 104. The residue 134r may be formed on the insulating material 118 (FIG. 4). In some embodiments, due to the minimized residue 134r in the corners, the side surfaces of the remaining first sacrificial layer 103 may be substantially aligned with the corresponding side surfaces of the sacrificial gate electrode layers 134, as shown in FIG. 10C. In some embodiments, a lateral distance between the side surface of the remaining first sacrificial layer 103 and the corresponding side surface of the sacrificial gate electrode layer 134 may range from about 0 nm to about 2 nm. Furthermore, the side surface of the sacrificial gate electrode layer 134 may be substantially straight, as a result of minimized residue 134r in the corners. In some embodiments, an angle A is formed between the side surface of the sacrificial gate electrode layer 134 and the top surface of the topmost first semiconductor layer 106, and the angle A ranges from about 95 degrees to about 105 degrees, as shown in FIG. 10C. The sacrificial gate electrode layer 134, the portion of the first sacrificial layer 103 disposed under the sacrificial gate electrode layer 134, and the first and second mask layers 202, 204 (not shown) form a sacrificial gate structure 130. While two sacrificial gate structures 130 are shown in FIG. 10C, three or more sacrificial gate structures 130 may be arranged along the X direction in some embodiments.

In some embodiments, as shown in FIG. 10B, an angle B is formed between the side surface of the second semiconductor layer 108 and the side surface of the sacrificial gate electrode layer 134. As shown in FIG. 10A, the side surface of the top second semiconductor layer 108 and the side surface of the sacrificial gate electrode layer 134 form the angle B1, the side surface of the middle second semiconductor layer 108 and the side surface of the residue 134r form the angle B2, and the side surface of the bottom second semiconductor layer 108 and the side surface of the residue 134r form the angle B3. The angle B1 may range from about 90 degrees to about 92 degrees, the angle B2 may range from about 90 degrees to about 94 degrees, and the angle B3 may range from about 90 degrees to about 98 degrees. In some embodiments, the angles B1, B2, B3 are substantially the same due to the minimum amount of residue 134r. In some embodiments, the angle B3 is greater than the angle B2, which is greater than the angle B1, due to the existence of the residue 134r.

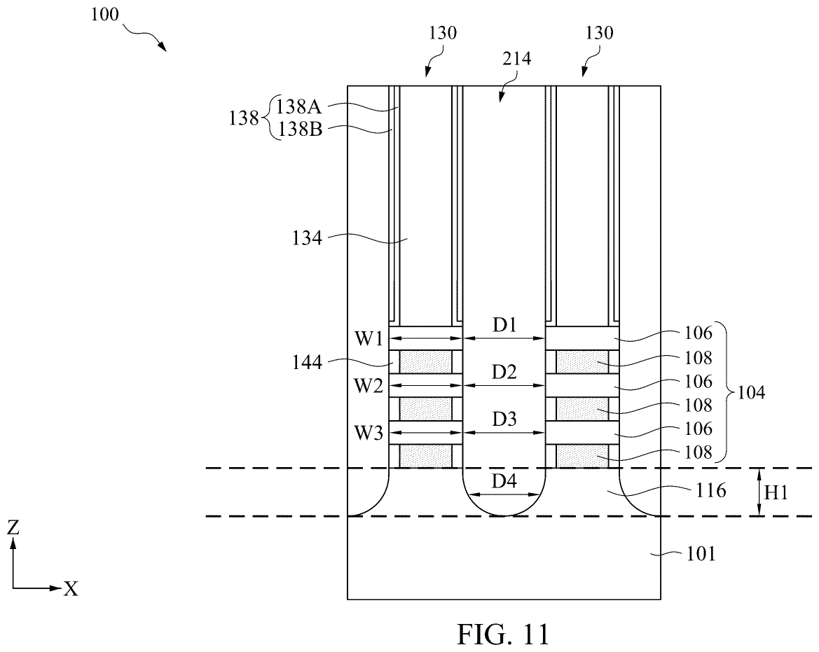

Next, as shown in FIG. 11, gate spacers 138 are formed on sidewalls of the sacrificial gate structures 130. The first and second mask layers 202, 204 are omitted in FIG. 11 for clarity. The gate spacers 138 may be formed by conformally depositing one or more layers, such as first gate spacer 138A and second gate spacer 138B, as shown in FIG. 11, and then anisotropically etching the one or more layers, for example. The gate spacers 138A, 138B may be made of a dielectric material such as silicon oxide, silicon nitride, silicon carbide, silicon oxynitride, SiCN, silicon oxycarbide, SiOCN, and/or combinations thereof. The portions of the fin structures 112 that are covered by the sacrificial gate electrode layer 134 of the sacrificial gate structure 130 serve as channel regions for the semiconductor device structure 100.

As shown in FIG. 11, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Next, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144, as shown in FIG. 11. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

As shown in FIG. 11, the top first semiconductor layer 106 has a width W1, the middle first semiconductor layer 106 has a width W2, and the bottom first semiconductor layer 106 has a width W3. A distance D1 is between horizontally adjacent top first semiconductor layers 106, a distance D2 is between horizontally adjacent middle first semiconductor layers 106, a distance D3 is between horizontally adjacent bottom first semiconductor layers 106, and a distance D4 between horizontally adjacent substrate portions 116. The distance D4 is measured at a location about haft of the height H1, which is measured from the bottom of the bottom second semiconductor layer 108 to the bottom of the opening 214. In some embodiments, because the thickness of the second mask layer 204 (FIG. 7G) is reduced, the process to recess the exposed portions of the fin structures 112 is performed in the openings 214 having a low aspect ratio, compared to the thicker second mask layer 204. With the low aspect ratio openings 214, the side surfaces of the first semiconductor layers 106 are substantially straight, as shown in FIG. 11. In some embodiments, the widths W1, W2, W3 may be substantially the same, and the distances D1, D2, D3 may be substantially the same. In some embodiments, the difference between W1 and W3 may range from about 0 nm to about 1 nm. In some embodiments, the distance D4 is less than the distance D1, D2, D3, and the difference between the distance D4 and the distance D1, D2, D3 is less than about 2 nm.

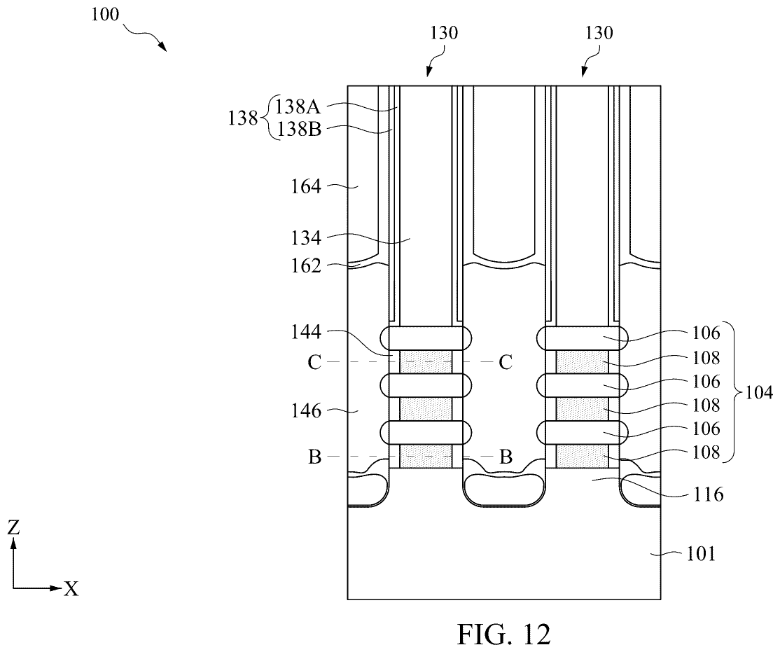

As shown in FIG. 12, source/drain (S/D) regions 146 are formed from the substrate portion 116. The S/D regions 146 may grow both vertically and horizontally to form facets, which may correspond to crystalline planes of the material used for the first semiconductor layers 106. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

Next, as shown in FIG. 12, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 10.

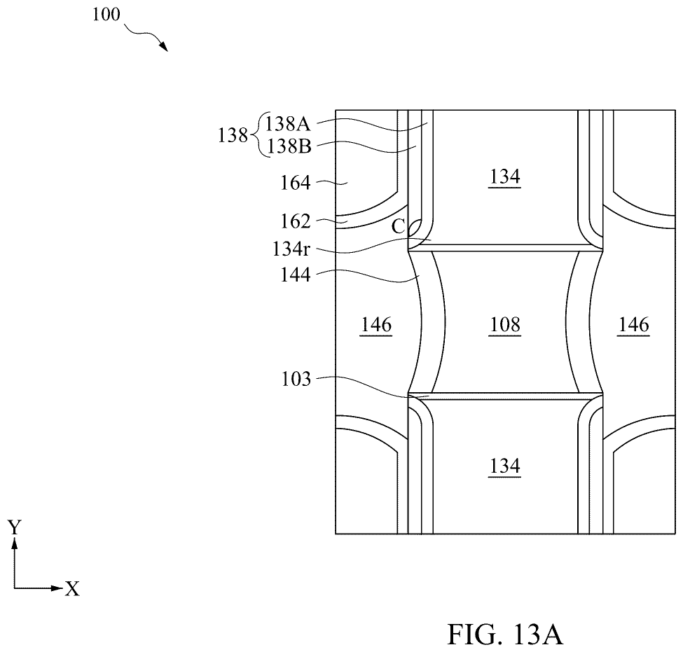

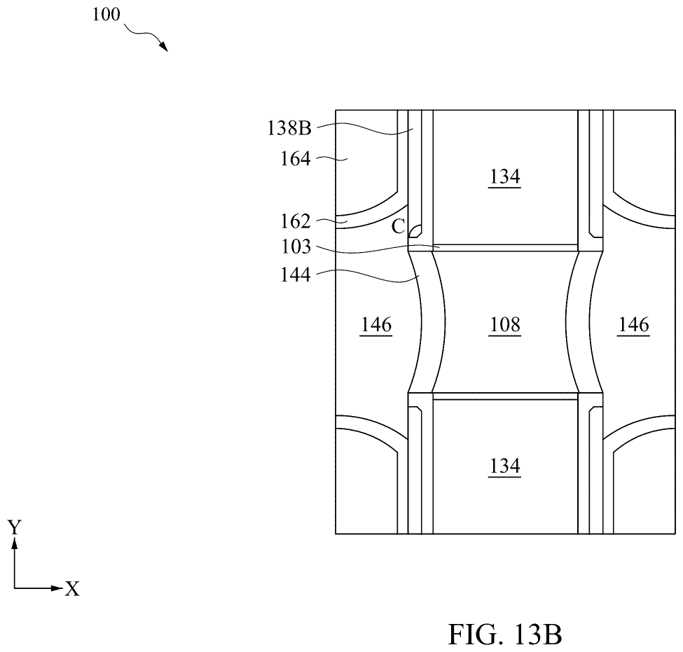

FIGS. 13A and 13B are cross-sectional top views of the semiconductor device structure 100 taken along line B-B and line C-C of FIG. 12, respectively, in accordance with some embodiments. FIG. 13A is a cross-sectional top view of a portion of the semiconductor device structure 100 taken along line B-B of FIG. 12, which is across the bottommost second semiconductor layer 108. As shown in FIG. 13A, in some embodiments, the residue 134r remains adjacent the bottommost second semiconductor layer 108. In some embodiments, because of the existence of the residue 134r, the portion of the first gate spacer 138A includes a straight portion in contact with the sidewall of the sacrificial gate electrode layer 134 and an end portion in contact with the S/D region 146, and an angle C is formed between the straight portion and the end portion. In some embodiments, the angle C is an obtuse angle due to the existence of the residue 134r, as shown in FIG. 13A. For example, the angle C may range from about 95 degrees to about 130 degrees. In some embodiments, the angle C is less than 130 degrees. If the angle B is greater than about 130 degrees, the gap between the first gate spacer 138A and the first sacrificial layer 103 may be too large. As a result, the first sacrificial layer 103 may be removed to expose the S/D region 146 during the removal of the sacrificial gate structure 130. With the angle C being less than about 130 degrees, the gap between the first gate spacer 138A and the first sacrificial layer 103 is small, and the portion of the first sacrificial layer 103 in contact with the S/D region 146 is not removed during the removal of the sacrificial gate structure 130. Furthermore, because of the small gap between the first gate spacer 138A and the first sacrificial layer 103, the process window for removing the sacrificial gate structure 130 may be enlarged.

FIG. 13B is a cross-sectional top view of a portion of the semiconductor device structure 100 taken along line C-C of FIG. 12, which is across the topmost second semiconductor layer 108. As shown in FIG. 13B, the residue 134r is not present adjacent the topmost second semiconductor layer 108. Without the residue 134r, the portion of the first sacrificial layer 103 is removed during the patterning of the first sacrificial layer 103 not covered by the sacrificial gate electrode layer 134. Thus, the first sacrificial layer 103 is not located between the gate spacer 138 and the dielectric spacer 144. As a result, the angle C between the straight portion and the end portion of the first gate spacer 138A is less than the angle C located adjacent the bottommost second semiconductor layer 108 (FIG. 13A). In some embodiments, the angle C adjacent the topmost second semiconductor layer 108 is a right angle. The angle C adjacent the middle second semiconductor layer 108 may be between the angle C adjacent the topmost second semiconductor layer 108 and the angle C adjacent the bottommost second semiconductor layer 108. In other words, the angle C increases in a direction towards the substrate 101.

As shown in FIG. 14, the sacrificial gate structure 130 and the second semiconductor layers 108 are removed. The removal of the sacrificial gate structure 130 and the semiconductor layers 108 forms an opening between gate spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the exposed portions of the first sacrificial layer 103, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

As shown in FIG. 14, as mentioned above, the low aspect ratio openings 214 may lead to substantially straight side surfaces of the first semiconductor layers 106 and the second semiconductor layers 108. After forming the dielectric spacers 144, the side surfaces of the dielectric spacers 144 are also substantially straight. In some embodiments, the dielectric spacer 144 located below the bottom first semiconductor layer 106 has a side surface that forms an angle D with a plane P defined by the bottom surface of the gate dielectric layer 170. The dielectric spacer 144 located above the bottom first semiconductor layer has a side surface that forms an angle E with the plane P, and the dielectric spacer 144 located below the top first semiconductor layer 106 has a side surface that forms an angle F with the plane P. The angle F may range from about 90 degrees to about 90.5 degrees, the angle E may range from about 90.5 degrees to about 91 degrees, and the angle D may range from about 94 degrees to about 97 degrees. In some embodiments, the angle D is substantially greater than the angle E, which is substantially greater than the angle F. In some embodiments, because the distances D1, D2, D3 are substantially the same, the portion of the S/D region 146 located between the horizontally adjacent first semiconductor layers 106 may have a substantially constant width along the X direction.

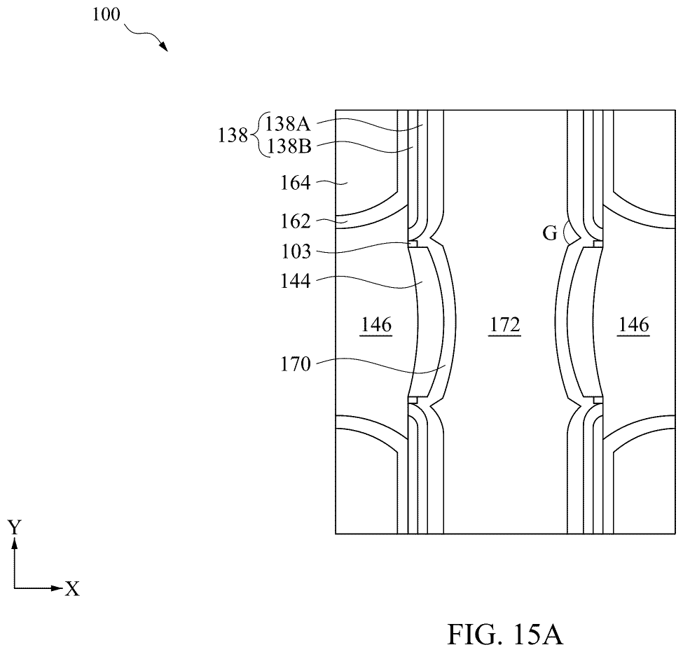

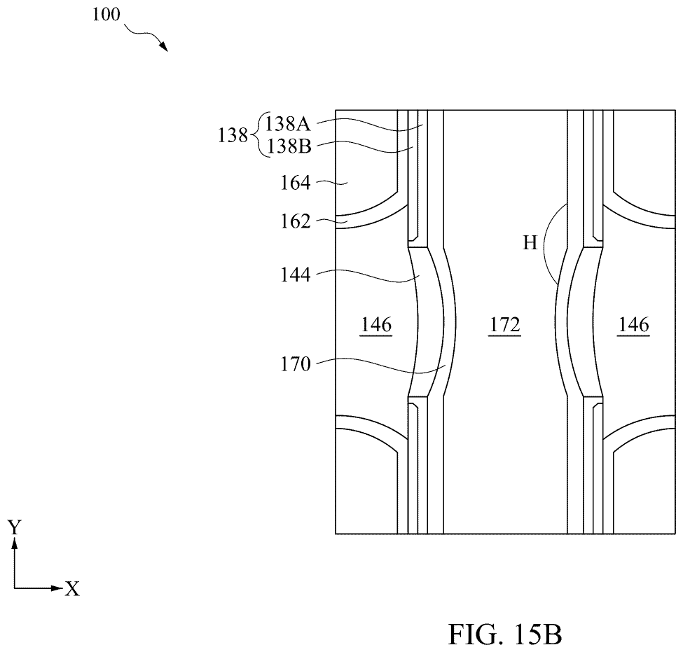

FIGS. 15A and 15B are cross-sectional top views of the semiconductor device structure 100 taken along line D-D and line E-E of FIG. 14, respectively, in accordance with some embodiments. FIG. 15A is a cross-sectional top view of a portion of the semiconductor device structure 100 taken along line D-D of FIG. 14, which is across the portion of the gate electrode layer 172 located below the bottommost first semiconductor layer 106. As shown in FIG. 15A, the portion of the first sacrificial layer 103 located between the gate spacer 138 and the dielectric spacer 144 remains and separates the gate dielectric layer 170 and the S/D region 146. In some embodiments, the thickness of the portion of the first sacrificial layer 103 located between the gate spacer 138 and the dielectric spacer 144 along the Y direction is less than about 1 nm, such as from about 0.3 nm to about 1 nm. In some embodiments, the first sacrificial layer 103 is in contact with the S/D region 146, the first gate spacer 138A, and the dielectric spacer 144. In some embodiments, the gate dielectric layer 170 includes a first portion located adjacent the gate spacer 138 and a second portion located adjacent the dielectric spacer 144. An angle G may be formed between the first and second portions of the gate dielectric layer 170, as shown in FIG. 15A. In some embodiments, the angle G ranges from about 150 degrees to about 165 degrees.

FIG. 15B is a cross-sectional top view of a portion of the semiconductor device structure 100 taken along line E-E of FIG. 14, which is across the portion of the gate electrode layer 172 located below the topmost first semiconductor layer 106. As shown in FIG. 15B, the gate dielectric layer 170 and the S/D region 146 are separated by the gate spacer 138 and the dielectric spacer 144. In some embodiments, the thickness of the gate spacer 138 (the combined thickness of the first and second gate spacers 138A, 138B) may range from about 5 nm to about 10 nm, and the thickness of the dielectric spacer 144 may be the same as the thickness of the gate spacer 138. With such thick dielectric materials between the gate dielectric layer 170 and the S/D region 146, the risk of electrical short between the gate electrode 172 and the S/D region 146 is reduced. In addition, because the gate spacer 138 is in contact with the dielectric spacer 144, the process window for removing the sacrificial gate structure 130 may be enlarged. For example, when removing the sacrificial gate electrode layer 134, the portion of the first sacrificial layer 103 covered by the sacrificial gate electrode layer 134, and the second semiconductor layers 108, the risk of exposing the S/D regions 146 is reduced. In some embodiments, the gate dielectric layer 170 includes a first portion located adjacent the gate spacer 138 and a second portion located adjacent the dielectric spacer 144. An angle H may be formed between the first and second portions of the gate dielectric layer 170, as shown in FIG. 15B. In some embodiments, the angle H ranges from about 170 degrees to about 180 degrees. In some embodiments, the angle H is substantially greater than the angle G.

Embodiments of the present disclosure provide methods for forming semiconductor device structure 100. The methods includes forming a second mask layer 204 having a thickness ranging from about 60 nm to about 65 nm. Furthermore, the processes for patterning a second sacrificial layer 105 to form sacrificial gate electrode layers 134 includes processes that can remove byproducts. Some embodiments may achieve advantages. For example, the second mask layer 204 having the thickness ranging from about 60 nm to about 65 nm leads to an opening 214 having a smaller aspect ratio, and along with the processes for patterning the second sacrificial layer 105, the amount of residue 134r formed in the corners of the sacrificial gate electrode layer 134 is minimized. The minimized residue 134r can lead to enlarged process window for removing the sacrificial gate structure 130. Furthermore, the risk of electrical short between the gate electrode layer 172 and the S/D region 146 is reduced.

An embodiment is a method for forming a semiconductor device structure. The method includes forming a fin structure from a substrate, depositing a first sacrificial layer around the fin structure, depositing a second sacrificial layer on the first sacrificial layer, and depositing a first mask layer over the second sacrificial layer. The first mask layer has a thickness ranging from about 60 nm to about 65 nm. The method further includes performing a first etch process to remove portions of the first mask layer, performing multiple processes to remove portions of the second sacrificial layer to form two or more sacrificial gate electrode layers, removing a portion of the fin structure to expose a substrate portion, and forming a source/drain region over the substrate portion.

Another embodiment is a method. The method includes forming a fin structure from a substrate, depositing a first sacrificial layer around the fin structure, depositing a second sacrificial layer on the first sacrificial layer, and performing multiple processes to remove portions of the second sacrificial layer to form two or more sacrificial gate electrode layers. The performing multiple processes includes performing a main etch process and performing a soft landing process. The soft landing process includes a plasma etch process including a plasma power having a first pulsing scheme, and the first pulsing scheme includes a first active period followed by a first off period during a time period, and the plasma power is pulsed multiple times during the first active period and is off during the first off period.

A further embodiment is a method. The method includes forming a fin structure from a substrate, depositing a first sacrificial layer around the fin structure, depositing a second sacrificial layer on the first sacrificial layer, and performing multiple processes to remove portions of the second sacrificial layer to form two or more sacrificial gate electrode layers. The performing multiple processes includes performing a main etch process, performing a breakthrough process, performing a first soft landing process, and performing an over etching process. The over etching process includes a plasma etch process, and a plasma power, a first bias power, and a second bias power are applied during the plasma etch process. The method further includes removing the two or more sacrificial gate electrode layers and depositing a gate electrode layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a semiconductor device structure, comprising:
forming a fin structure from a substrate;
depositing a first sacrificial layer around the fin structure;
depositing a second sacrificial layer on the first sacrificial layer;
depositing a first mask layer over the second sacrificial layer, wherein the first mask layer has a thickness ranging from about 60 nm to about 65 nm;
performing a first etch process to remove portions of the first mask layer;
performing multiple processes to remove portions of the second sacrificial layer to form two or more sacrificial gate electrode layers;
removing a portion of the fin structure to expose a substrate portion; and
forming a source/drain region over the substrate portion.

2. The method of claim 1, further comprising depositing a second mask layer on the second sacrificial layer, wherein the first mask layer is deposited on the second mask layer.

3. The method of claim 2, further comprising depositing a third mask layer on the second mask layer.

4. The method of claim 3, further comprising forming a resist structure on the third mask layer.

5. The method of claim 4, further comprising:
performing a second etch process to remove portions of the resist structure;
performing a third etch process to remove portions of the third mask layer; and
performing a fourth etch process to remove portions of the second mask layer.

6. The method of claim 5, wherein the first, second, third, and fourth etch processes are distinct processes.

7. The method of claim 1, wherein a residue is formed in corners of the two or more sacrificial gate electrode layers after the multiple processes.

8. A method for forming a semiconductor device structure, comprising:
forming a fin structure from a substrate;
depositing a first sacrificial layer around the fin structure;
depositing a second sacrificial layer on the first sacrificial layer; and
performing multiple processes to remove portions of the second sacrificial layer to form two or more sacrificial gate electrode layers, comprising:
performing a main etch process; and
performing a soft landing process, wherein the soft landing process comprises a plasma etch process including a plasma power having a first pulsing scheme, and the first pulsing scheme comprises a first active period followed by a first off period during a time period, wherein the plasma power is pulsed multiple times during the first active period and is off during the first off period.

9. The method of claim 8, wherein the first active period is about 80 percent to about 90 percent of the time period, and the first off period is about 10 percent to about 20 percent of the time period.

10. The method of claim 9, wherein the plasma power has a duty cycle ranging from about one percent to about six percent during the first active period.

11. The method of claim 8, wherein the plasma etch process further includes a bias power having a second pulsing scheme, and the second pulsing scheme comprises a second active period followed by a second off period during the time period.

12. The method of claim 11, wherein the second active period is about 80 percent to about 90 percent of the time period, and the second off period is about 10 percent to about 20 percent of the time period.

13. The method of claim 12, wherein the bias power has a duty cycle ranging from about one percent to about eight percent during the second active period.

14. The method of claim 8, wherein a vacuum pump is removing byproducts from a processing chamber during the first off period.

15. The method of claim 8, further comprising depositing a mask layer over the second sacrificial layer, wherein the mask layer has a thickness ranging from about 60 nm to about 65 nm.

16. A method for forming a semiconductor device structure, comprising:
forming a fin structure from a substrate;
depositing a first sacrificial layer around the fin structure;
depositing a second sacrificial layer on the first sacrificial layer;
performing multiple processes to remove portions of the second sacrificial layer to form two or more sacrificial gate electrode layers, comprising:
performing a main etch process;
performing a breakthrough process;
performing a first soft landing process; and
performing an over etching process, wherein the over etching process comprises a plasma etch process, and a plasma power, a first bias power, and a second bias power are applied during the plasma etch process;
removing the two or more sacrificial gate electrode layers; and
depositing a gate electrode layer.

17. The method of claim 16, further comprising performing a passivation process after the first soft landing process.

18. The method of claim 17, further comprising performing a second soft landing process after the passivation process.

19. The method of claim 18, further comprising performing a flush process after the second soft landing process, wherein the over etching process is performed after the flush process.

20. The method of claim 19. wherein the flush process is different from the second soft landing process and the over etching process.
